(19) United States
(12) Patent Application Publication
(10) Pub. No.: US 2023/0132980 A1
(43) Pub. Date: May 4, 2023

(54) VAPOR CHAMBER

(71) Applicant: Commissariat à l'Énergie Atomique et aux Énergies Alternatives, Paris (FR)

(72) Inventors: Jean-Philippe Colonna, Grenoble Cedex 9 (FR); Perceval Coudrain, Grenoble Cedex 9 (FR); Luc Frechette, Sherbrooke (CA); Quentin Struss, Grenoble (FR)

(73) Assignee: Commissariat à l'Énergie Atomique et aux Énergies Alternatives, Paris (FR)

(21) Appl. No.: 17/980,140

(22) Filed: Nov. 3, 2022

(30) Foreign Application Priority Data
Nov. 4, 2021 (FR) 2111711

(51) Int. Cl. F28D 15/02; F28F 21/06; F28F 21/08

(52) U.S. Cl. CPC F28D 15/0233; F28D 15/0283; F28F 21/06; F28F 21/08; F28F 2220/00

(57) ABSTRACT

The present description concerns a method of manufacturing a vapor chamber (300) comprising the following steps:
(a) etching, in a first substrate (301), at least one first cavity (303) and at least one channel (313) extending from an upper surface (305) of said first substrate (301), a first end (315) of said channel (313) emerging into said at least one cavity (303);
(b) bonding a lower surface of a plate (309) to the upper surface (305) of said first substrate (301), the plate (309) comprising at least one first region made of a ductile material (321) arranged in front of said first end (315) of said channel (313);
(c) filling said channel (313) with a cooling fluid (319); and
(d) closing said cavity (303) by applying a pressure on said region of ductile material of the plate (309) to obstruct said first end (315) of said channel (313).

### TECHNICAL BACKGROUND

The present disclosure generally concerns the cooling of systems, such as mechanical systems or electronic systems. More particularly, the disclosure concerns a cooling device of “vapor chamber” type and its manufacturing method.

### PRIOR ART

Many systems, such as mechanical systems or electronic systems, may be subject to overheating phenomena likely to damage them or to damage the environment where they are operating. An efficient way to counter overheating phenomena is the use of cooling devices.

There exist several types of cooling devices, such as air conditioning systems, heat pipes, vapor chambers, etc. It is current to associate a cooling device with a system likely to overheat by positioning it close to a hot spot of the system.

It would be desirable to be able at least partly improve the disadvantages of existing cooling devices and of their manufacturing methods.

### SUMMARY OF THE INVENTION

There is a need for higher-performance cooling devices.

There is a need for higher-performance vapor chambers.

There is a need for higher-performance cooling device manufacturing methods.

There is a need for vapor chamber manufacturing methods better adapted to the series manufacturing of vapor chambers.

An embodiment overcomes all or part of the disadvantages of known vapor chambers.

An embodiment overcomes all or part of the disadvantages of known vapor chamber manufacturing methods.

An embodiment provides a method of manufacturing a vapor chamber comprising the following successive steps:

(a) etching, in a first substrate, at least one first cavity extending from an upper surface of said first substrate, and at least one channel extending from the upper surface of said first substrate, a first end of said channel emerging into said at least one cavity;
(b) bonding a lower surface of a plate to the upper surface of said first substrate, the plate comprising at least a first region made of a ductile material arranged in front of said first end of said channel;
(c) filling said channel with a cooling fluid; and
(d) closing said cavity by applying a pressure on said region made of a ductile material of the plate to obstruct said first end of said channel.

According to an embodiment, during step (d), said first cavity is tightly closed.

According to an embodiment, the first substrate is made of a material selected from the group comprising: a semiconductor material, silicon, a metal, a metal alloy, glass.

According to an embodiment, the ductile material is made of a polymer material or of a metal such as copper, silver, aluminum, gold, or an alloy of these metals.

According to an embodiment, during step (a), second cavities are etched from the upper surface of said first substrate.

According to an embodiment, said channel couples said first cavity and said second cavities.

According to an embodiment, the first and second cavities are coupled in series by said channel.

According to an embodiment, the first and second cavities are coupled in parallel by said channel.

According to an embodiment, said plate comprises an opening arranged above a first portion of said channel.

According to an embodiment, the first portion of the channel is a second end of said channel.

According to an embodiment, said channel comprises a third end emerging onto an opening at the periphery of the first substrate.

According to an embodiment, the method further comprises a step (e) executed between steps (b) and (c), during which a quasi-vacuum or vacuum is created in said at least one first cavity.

According to an embodiment, said first region of said plate extends all along the length of said plate.

According to an embodiment, the cooling liquid is selected from the group comprising: water, helium, hydrogen, oxygen, nitrogen, sulfur, neon, argon, methane, krypton, mercury, ammonia (NH3), acetone (C3H6O), ethane (C2H6), pentane (C5H12), heptane (C7H16), ethanol (C2H5OH), methanol (CH3OH), ethylene glycol (C2H6O2), toluene (C7H8), naphthalene (C10H8), trichlorofluoromethane (CCl3F, also known under trade name Freon 11), dichlorofluoromethane (CHClL2F, also known under trade name Freon 21), chlorodifluoromethane (CHClF2, also known under trade name Freon 22), 1,1,2-Trichloro-1,2,2-trifluoroethane (C2Cl3F3, also known under trade name Freon 113), the fluid known under trade name Flutec PP2, the fluid known under trade name Flutec PP9, the fluid known under trade name Dowtherm, the fluid known under trade name Novec, and derivatives and mixtures of these fluids.

Another embodiment provides a vapor chamber manufactured according to the previously-described method.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows a simplified functional cross-section view of a vapor chamber associated with an electronic device;

FIG. 2 shows a simplified cross-section view of an embodiment of a vapor chamber;

FIG. 3 shows three simplified top views of embodiments of vapor chambers of FIG. 2;

FIG. 4 shows two cross-section views of a portion of a vapor chamber of FIG. 2;

FIG. 5 shows two cross-section views of another portion of a vapor chamber of FIG. 2;

FIG. 6 shows a top view schematically illustrating an alternative embodiment of a vapor chamber of FIG. 2;

FIG. 7 shows three cross-section views illustrating steps of an implementation mode of a method of manufacturing vapor chambers of FIG. 2;

FIG. 8 shows three cross-section views illustrating other steps of the implementation mode of the method of FIG. 7;

FIG. 9 shows four cross-section views illustrating other steps of the implementation mode of the method of FIG. 7;

FIG. 10 shows four cross-section views illustrating steps of an implementation mode of another method of manufacturing the vapor chamber of FIG. 2;

FIG. 11 shows four cross-section views illustrating steps of an implementation mode of still another method of manufacturing vapor chambers of FIG. 2;

FIG. 12 shows two cross-section views illustrating steps of an implementation mode of still another method of manufacturing the vapor chamber of FIG. 2;

FIG. 13 shows six cross-section views illustrating steps of an implementation mode of a method of manufacturing an electronic system; and

FIG. 14 shows two cross-section views illustrating other steps of the implementation mode of the method of FIG. 13.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

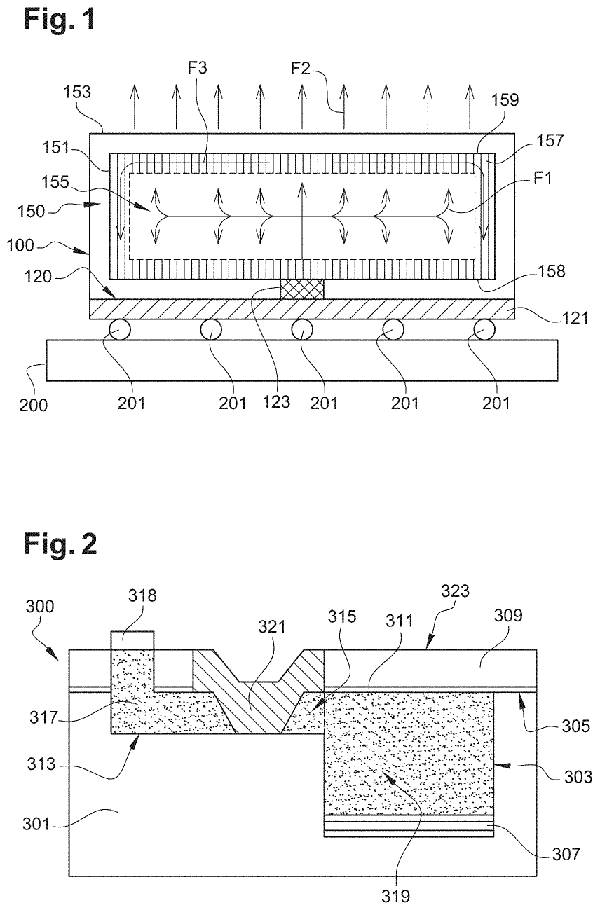

FIG. 1 is a functional simplified cross-section view of an electronic system 100 comprising a vapor chamber 150.

Electronic system 100 is assembled on a substrate 200, for example, via connection balls 201. Substrate 200 is for example a solid substrate or a printed circuit board, etc.

Electronic system 100 is formed of an electronic device 120 and of vapor chamber 150.

Electronic device 120 is of any type, and may comprise all or part of an electronic component, one or a plurality of components, one or a plurality of circuits, for example, one or a plurality of printed circuits, etc. These components are represented, in FIG. 1, by a layer 121. Device 120 further comprises a hot spot 123, that is, an area likely to generate a significant heat, or an area likely to overheat. This hot spot may correspond to a component, an assembly of components, a lead, etc. Hot spot 123 is represented, in FIG. 1, by a block 123.

Vapor chamber 150 comprises a cavity 151 formed in a substrate 153. Cavity 151 is filled with a cooling fluid 155. On the walls of cavity 151 is arranged a capillary wick structure 157.

Vapor chamber 150 is arranged to help cooling the hot spot 123 of device 120. A lower surface 158 of cavity 151 is positioned against the hot spot 123 of electronic device 120, this surface is called evaporator. An upper surface 159 of electronic device 120, opposite to surface 158, is called condenser. Upper surface 159 may be placed against a heat sink, not shown in FIG. 1.

Vapor chamber 150 operates as follows. In the idle state, that is, when hot spot 123 dissipates no heat, fluid 155 is at equilibrium between its gaseous phase, or vapor phase, and its liquid phase. When hot spot 123 generates heat, the fluid 155 directly close to hot spot 123 evaporates, and creates a motion of vapor within cavity 151. More particularly, fluid 155 in vapor phase moves away from surface 158, for example, towards surface 159, which is symbolized, in FIG. 1, by an arrow F1. Once the fluid 155 in vapor phase reaches surface 159 of the cavity, it encounters capillary wick structure 157 and condenses to recover its liquid phase. The heat is thus released on the capacitor side, for example in a heat sink. This phenomenon is symbolized by arrows F2. The temperature of fluid 155 then decreases and it returns to its initial position by following arrows F3.

FIG. 2 is a cross-section view of an embodiment of a vapor chamber 300.

Vapor chamber 300 is formed in a substrate 301. According to an embodiment, substrate 301 is made of a semiconductor material, for example, silicon, or is made of a metal or a metal alloy, or glass. Vapor chamber 300 comprises a cavity 303 extending from an upper surface 305 of substrate 301. Cavity 303 has a depth smaller than the thickness of substrate 301, for example in the range from 1 μm to 1 mm, preferably from 10 μm to 800 μm. According to an example, cavity 303 has, in top view, a substantially rectangular shape, for example, substantially square, having an area in the range from 1 mm² to 10 cm². A stack of layers 307 is deposited at the bottom of cavity 303 to form a capillary wick structure. According to an example, capillary wick structure 307 is a structure called “wick” capable of comprising porous structures such as grooves or metal foams, such as copper foams having pores with minimum dimensions in the order of 1 μm. According to an example, the capillary wick structure may be a porous structure manufactured from a substrate, for example, made of copper or of silicon, having grooves, for example with a width in the order of from 1 μm to 1 mm, and/or columns, for example with a width in the order of from 1 μm to 1 mm, formed therein. The bottom of cavities 303 is the condenser of vapor chamber 300.

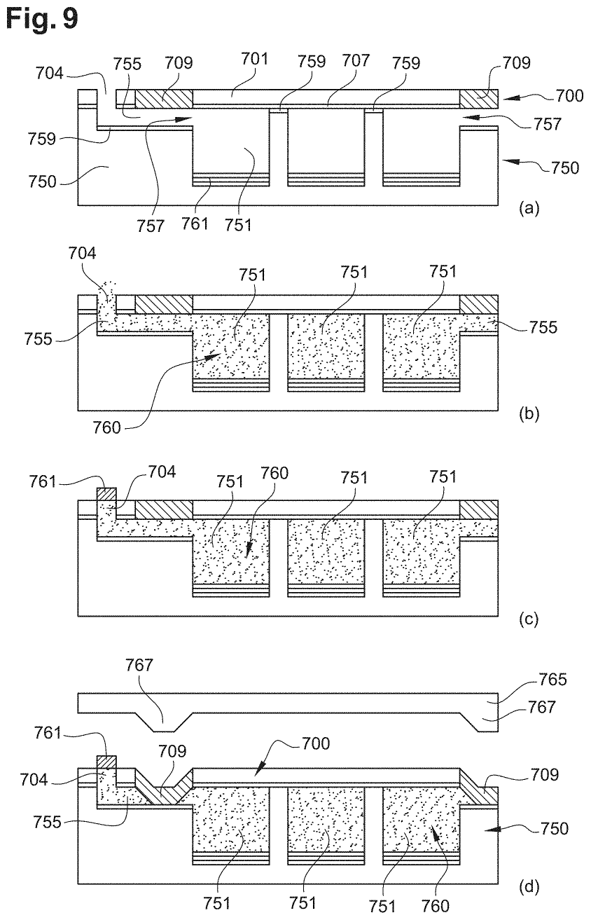

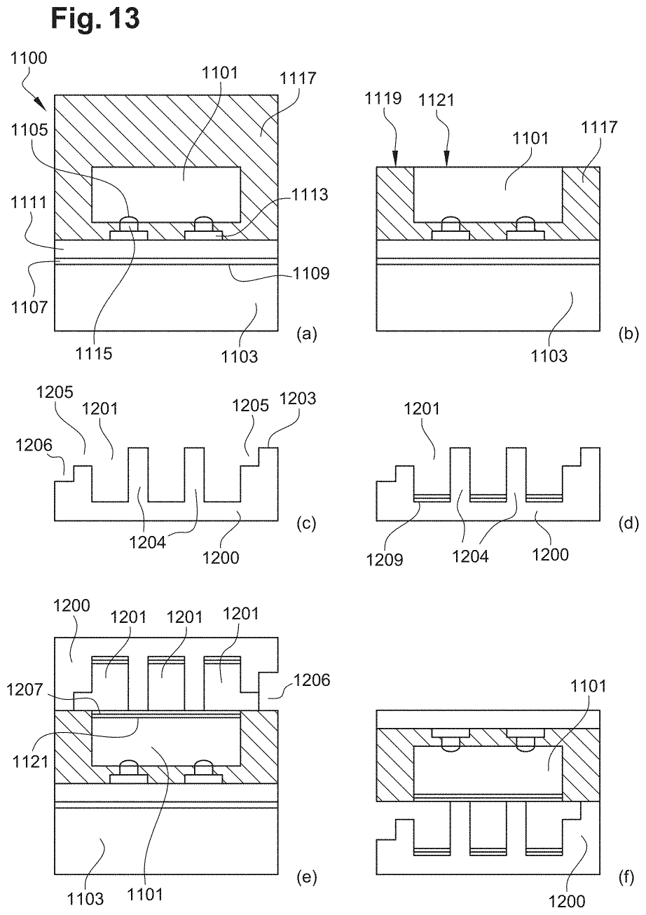

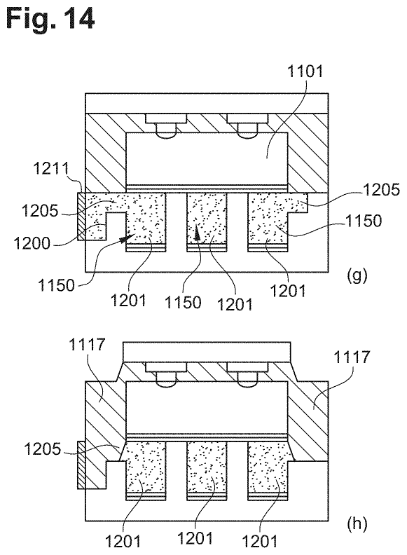

The upper opening of cavity 303 is tightly closed by a plate 309. Plate 309 is for example made of the same material as substrate 301, for example, silicon or a metal. Plate 309 is attached, for example, bonded, to substrate 301. According to an example, when substrate 301 and plate 309 are made of silicon, the upper surface 305 of substrate 301 and the lower surface of plate 309 are oxidized to perform a molecular bonding based on silicon oxide. In FIG. 2, the bonding area of substrate 301 and of plate 309 is represented by an adhesive layer 311. Other examples of tight assembly method are disclosed in relation with FIG. 9. Plate 309 forms the evaporator of vapor chamber 300. According to a variant, plate 309 may be directly formed from an electronic device to be cooled, a manufacturing method illustrating this case is described in relation with FIGS. 13 and 14.

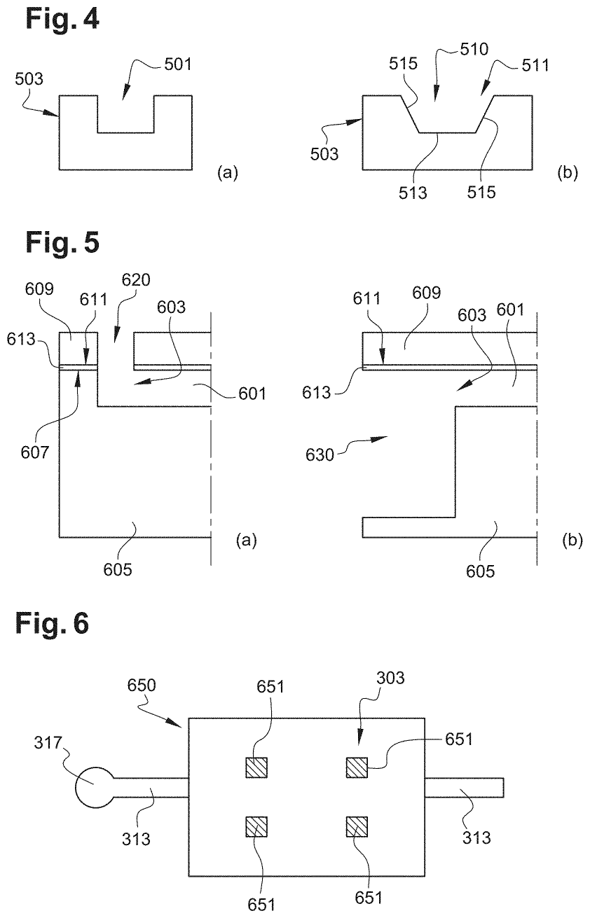

According to an embodiment, vapor chamber 300 further comprises a channel 313 for filling cavity 303. Channel 313 is a trench formed from the upper surface 305 of substrate 301. According to an embodiment, channel 313 is shallower than cavity 303. Examples of cross-section shapes of channel 313 are described in relation with FIG. 4. A first end 315 of the channel emerges onto cavity 303, and a second end 317 of channel 313 is used as a filling hole. The second end, or filling hole, 317 is closed by a plug 318. Plug 318 may be formed by seal welding. The arrangement of filling hole 317 is described in further detail in relation with FIG. 5.

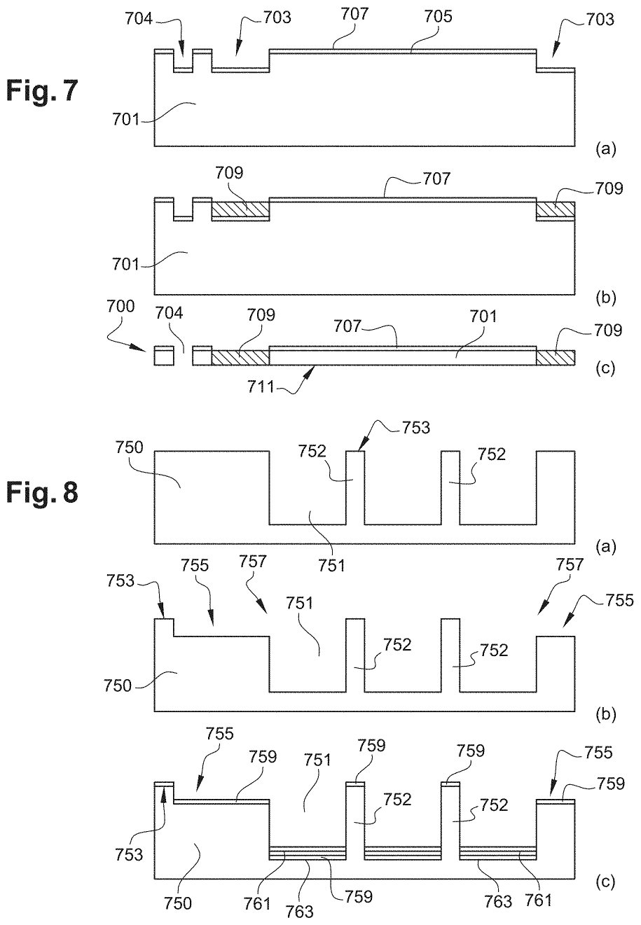

Cavity 303 is filled with a cooling fluid 319. Fluid 319 has been introduced into cavity 303 through channel 313, and end 315 has been tightly sealed, after filling, by the ductile material 321 forming part of plate 309. Ductile material 321 may be made of a polymer material, such an epoxy resin, or of a metal such as copper, silver, aluminum, gold, or an alloy of these metals. Implementation modes of vapor chamber manufacturing methods are described in relation with FIGS. 7 to 14.

Cooling fluid 319 is a fluid which, at the idle temperature of vapor chamber 300, is at equilibrium between its liquid phase and its gaseous phase. According to a variant, cooling fluid 319 may be at equilibrium between its liquid phase, its gaseous phase, and its solid phase. The idle temperature of vapor chamber 300 is defined as being the normal operating temperature of the system to be cooled with which vapor chamber 300 is associated, that is, the operating temperature when the system to be cooled is not overheating. According to an embodiment, cooling fluid 319 is selected from the non-exhaustive group comprising: water, helium, hydrogen, oxygen, nitrogen, sulfur, neon, argon, methane, krypton, mercury, ammonia (NH₃), acetone (C₃H₆O), ethane (C₂H₆), pentane (C₅H₁₂), heptane (C₇H₁₆), ethanol (C₂H₅OH), methanol (CH₃OH), ethylene glycol (C₂H₆O₂), toluene (C₇H₈), naphthalene (C₁₀H₈), trichlorofluoromethane (CCl₃F, also known under trade name Freon 11), dichlorofluoromethane (CHCl₂F, also known under trade name Freon 21), chlorodifluoromethane (CHClF₂, also known under trade name Freon 22), 1,1,2-Trichloro-1,2,2-trifluoroethane (C2Cl3F3, also known under trade name Freon 113), the fluid known under trade name Flutec PP2, the fluid known under trade name Flutec PP9, the fluid known under trade name Dowtherm, the fluid known under trade name Novec, and derivatives and mixtures of these fluids.

A system to be cooled may be associated with vapor chamber 300 by being positioned, for example, on an upper surface 323 of plate 309, that is, on the evaporator side.

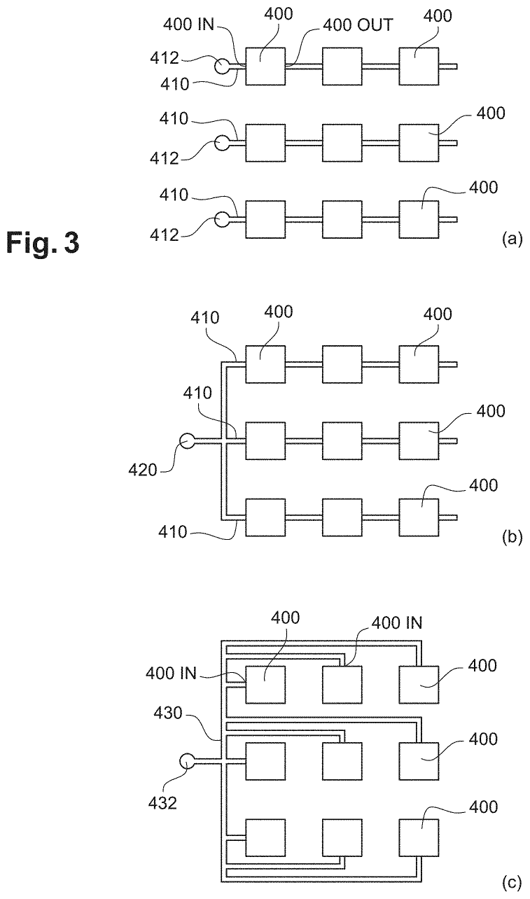

The advantages of vapor chamber 300 are described in relation with FIGS. 3 to 14.

FIG. 3 shows three top views (a), (b), and (c) of a plurality of a vapor chambers 400 of the type of the vapor chamber 300 described in relation with FIG. 2.

Each view (a), (b), (c) shows an example where nine vapor chambers 400 are simultaneously formed in a same substrate (not shown in views (a) to (c)). It is obvious that it is possible to simultaneously form more or less than nine vapor chambers 400 by adapting the arrangement thereof. Vapor chambers 400 are arranged in three rows and three columns. Vapor chambers 400 are simultaneously filled by being connected to common filling channels. Views (a) to (c) show different embodiments of common filling channels. More particularly, views (a) and (b) show embodiments where vapor chambers 400 are coupled “in series” and view (c) shows an embodiment where vapor chambers 400 are coupled “in parallel”.

View (a) shows an embodiment where all the vapor chambers 400 of a same row are coupled “in series” by a same filling channel 410. More particularly, each vapor chamber 400 comprises an inlet 400IN and an outlet 400OUT, each coupled to filling channel 410. Each vapor chamber 400 is coupled to the next one by filling channel 410. Each filling channel is ended by a filling hole 412. In other words, in the embodiment shown in view (a), three vapor chambers 400 are coupled in a same row by a same filling channel 410, and these three vapor chambers 400 are filled with a cooling fluid through a same filling hole 412.

According to a variant, all the vapor chambers of a same column may be coupled “in series” in the same way.

View (b) shows an embodiment, similar to that shown in view (a), where all the vapor chambers 400 of a same row are coupled “in series” by a same filling channel 410. Conversely to the embodiment of view (a), channels 410 are all coupled to a filing hole 420 common to all channels. In other words, in the embodiment shown in view (b), three vapor chambers 400 are coupled by a same filling channel 410, and the nine vapor chambers 400 are filled with a cooling fluid through a same filling hole 420.

According to a variant, all the vapor chambers of a same column may be coupled “in series” in the same way.

View (c) shows an embodiment where all the vapor chambers 400 are coupled “in parallel” by a filling channel 430. More particularly, vapor chambers 400 comprise a single inlet 400IN coupled to filling channel 430. Filling channel 430 is coupled to a single filling hole 432. Thus, the nine vapor chambers 400 are coupled by a same filling channel 430 and are filled with a cooling fluid through a same filling hole 432.

An advantage of the embodiments disclosed in FIG. 3 is that a plurality of vapor chambers may be simultaneously formed and filled with cooling fluid. Once the vapor chambers have been filled, the filling channels are sealed, and the vapor chambers may be individualized by using, for example, sawing methods.

FIG. 4 shows two cross-section views (a) and (b) of a filling channel of a cavity of a vapor chamber of the type of the filling channel 313 described in relation with FIG. 2 or of the channels 410 and 430 described in relation with FIG. 3. Views (a) and (b) illustrate different shapes capable of being used to form a channel for filling a cavity of a vapor chamber.

View (a) shows a filling channel 501 formed in a substrate 503. Filling channel 501 has, in cross-section, a rectangular or for example square shape.

View (b) shows a preferred embodiment of a filling channel 510 formed in substrate 503. Filling channel 501 has, in cross-section, a trapezoidal shape. More particularly, channel 510 has an upper opening 511 having a width greater than the width of its bottom 513. Thus, the walls 515 of channel 510 are not vertical but inclined.

Channels 501 and 510 are formed by using a step of masking, for example, by lithography, then a step of etching of substrate 503. According to an example, the depth of channels 501 and 510 may be in the range, for example, from 1 μm to 1 mm, for example from 10 to 800 μm.

FIG. 5 shows two cross-section views (a) and (b) of a hole for filling a cavity of a vapor chamber of the type of the filling hole 317 described in relation with FIG. 2 or of the type of the filling holes 412, 420, and 432 described in relation with FIG. 3.

Views (a) and (b) show a partial view of a vapor chamber of the type of that described in relation with FIG. 2. Views (a) and (b) more precisely show an end 603 of a filling channel 601 formed in a substrate 605. An upper surface 607 of substrate 605 is bonded to the lower surface 611 of a plate 609 as described in relation with FIG. 2, which is represented by an adhesive layer 613.

View (a) shows an embodiment of a “vertical” filling hole 620 having the end 603 of filling hole 601 coupled thereto. More particularly, filling hole 620 is formed in plate 609, and is arranged above end 603 during the bonding of plate 609 onto substrate 605. As illustrated in FIG. 5, filling hole 620 may have dimensions similar to the dimensions of filling channel 601, or filling hole 620 may be wider than channel 601. According to an example, hole 620 may be formed before or after the bonding of plate 609 onto substrate 601.

View (b) shows an embodiment of a “horizontal” filling hole 630 having the end 603 of filling channel 601 coupled thereto. More particularly, filling hole 630 is formed in substrate 605 and emerges onto the lateral edge of substrate 605. Filling hole 630 may have dimensions similar to the dimensions of filling channel 601 or, as illustrated in FIG. 5, filling hole 630 may be wider than channel 601. According to an example, hole 630 may be formed at the end of the manufacturing method, for example, by a sawing step.

FIG. 6 is a simplified and schematic top view showing an embodiment of a vapor chamber 650.

Vapor chamber 650 is a variant of the vapor chamber 300 described in relation with FIG. 2. Vapor chambers 300 and 650 have common elements, only their differences are highlighted herein. FIG. 6 shows the following elements of vapor chamber 650:

cavity 303;

filling channel 313; and

filling hole 317.

Vapor chamber 650 differs from vapor chamber 300 in that it comprises support pillars 651, or pillars 651, arranged in cavity 303 enabling to help the mechanical hold of plate 309 (not shown in FIG. 6) on cavity 303. In FIG. 6, four pillars 651 are shown. Those skilled in the art will be able to adjust the number and the location of pillars 651 to optimize the hold of plate 309 on cavity 303. Further, in FIG. 6, the pillars have been shown as having the shape of a beam with a substantially square cross-section but, according to another example, pillars 651 may have a substantially rectangular or substantially circular cross-section. Further, pillars 651 may also be covered with the capillary wick structure. Pillars 651 are for example made of a same material as that of the substrate having cavity 303 formed therein.

FIGS. 7 to 9 show cross-section views illustrating steps of an implementation mode of a method of manufacturing three vapor chambers of the type of the vapor chamber 300 described in relation with FIG. 2. More particularly, FIG. 7 shows three cross-section views (a), (b), and (c) illustrating steps of preparation of a plate of the type of the plate 309 described in relation with FIG. 2. FIG. 8 shows three cross-section views (a), (b), and (c) illustrating steps of preparation of a substrate of the type of the substrate 301 described in relation with FIG. 2. FIG. 9 shows four cross-section views (a), (b), (c), and (d) illustrating steps of forming of vapor chambers of the type of that described in relation with FIG. 2 by assembly of the plate of FIG. 7 and of the substrate of FIG. 8.

As previously mentioned, FIG. 7 illustrates steps of preparation of a plate 700 of the type of the plate 309 described in relation with FIG. 2.

View (a) of FIG. 7 illustrates the forming, in a substrate 701, of cavities 703 and 704. In view (a), one cavity 704 is shown and two cavities 703 are shown. According to an example, substrate 701 is for example made of a semiconductor material, for example, a material comprising silicon. Cavities 703 and 704 extend from an upper surface 705 of substrate 701. Cavities 703 are intended to be filled with ductile material, and cavity or cavities 704 are intended to form vertical filling holes of the type of that described in relation with FIG. 5. In top view, cavities 703 are wider than the vapor chamber filling channels. According to an alternative embodiment, cavity or cavities 704 may not be formed at this step, but after the assembly with the substrate described in relation with FIG. 9. According to another alternative embodiment, when the vapor chambers use one or a plurality of filling holes called horizontal, as described in relation with FIG. 5, cavity or cavities 704 are not formed.

According to an example, cavities 703 and 704 are formed by using a masking step, for example a lithography step such as a photolithography step, then a step of etching of the unmasked portions, for example by using a wet etching method, or a dry etching method, such as a dry reactive ion etching (DRIE).

View (a) further illustrates the optional forming of an adhesive layer 707 on the upper surface 705 of substrate 701. According to an example, the forming of an adhesive layer may be a deposition of the adhesive layer, for example, by inkjet deposition. According to another example, if substrate 705 is made of silicon, the forming of the adhesive layer may be a step of oxidation of the surface of the substrate to prepare a molecular bonding step.

View (b) illustrates a step of deposition of a ductile material 709 in cavities 703. Ductile material 709 may be a resin, a polymer, a metal, fusible glass, or also a combination or a stack of a plurality of these elements. The method of deposition of ductile material 709 depends on the nature of the ductile material. According to an example, the deposition method may comprise one or a plurality of anneal steps. Similarly, the thickness of ductile material 709 also depends on the nature of the ductile material.

According to an example, ductile material 709 may comprise an epoxy resin, such as a filled epoxy resin. In this case, methods of lamination type may be used, such as a WOLM (Plate Level Over Molding) method. The deposition step may be followed by an step of anneal, for example, a polymerization anneal. Ductile material 709 may have a maximum thickness in the order of 500 μm, for example, of 300 μm.

According to another example, ductile material 709 may comprise copper, silver, aluminum, gold, an alloy of metals used for solders, etc. In this case, the deposition method may be an electroplating, a metal paste silk-screening, a vapor phase deposition method, etc. The deposition step may be followed by an anneal step. Ductile material 709 may have a maximum thickness in the order of 100 μm.

For ductile material 709 to only be deposited in cavities 703, the rest of the structure of view (a) may be masked. According to a variant, ductile material 709 may be deposited over the entire structure of view (a) and then removed from the areas where it is not useful. In this case, the ductile material may be for example removed by a polishing method.

View (c) illustrates a step of thinning of the structure of view (b) to obtain plate 700. The structure of view (b) is thinned from a rear surface 711 of substrate 701 to reach the bottom of cavities 703 and 704 so as to leave ductile material 709 apparent. The thinning method is for example a grinding method. Plate 700 has thus been formed. Plate 700 may have a thickness in the range from 50 μm to 50 mm. According to an example, if plate 700 is made of silicon, its thickness is in the range from 500 μm to 1 mm.

As previously mentioned, FIG. 8 illustrates steps of preparation of a substrate 750 of the type of the substrate 301 described in relation with FIG. 2.

View (a) illustrates a step of etching of cavities 751 in substrate 750. The step of etching of cavities 751 may comprise a masking step and then a step of etching of substrate 750, such as a Bosch etch step. According to an embodiment, a cavity 751 is formed in substrate 750, cavity 751 being intended to form a vapor chamber. Cavity 751 extends from an upper surface 753 of substrate 750. According to an example of embodiment, cavities 751 may have a depth in the range from 5 μm to 1 mm, preferably in the range from 60 to 500 μm.

Further, pillars 752 are formed in cavity 751. Two pillars 752 are shown in the views of FIG. 8. Pillars 752 are of the same type as the pillars 651 described in relation with FIG. 6. Pillars 752 are for example formed by masking during the etching of cavity 751.

View (b) illustrates a step of etching of a filling channel 755 in substrate 750. Filling channel 755 has at least one end 757 which emerges onto cavity 751. Channel 755 has, in top view, a shape similar to those described in relation with FIG. 3. The step of etching of channel 755 may comprise a masking step and then a step of etching of substrate 750, such as a Bosch etch step. Channel 755 extends from the upper surface 753 of substrate 750. Channel 755 has a depth smaller than the depth of cavity 751. The channel preferably has a smaller depth than its width in top view, for example with a width-to-depth ratio in the range from 1 to 10. Channel 755 has a depth in the range from 10 to 200 μm. Channel 755 has a width in the range from 10 to 500 μm.

View (c) illustrates the optional forming of an adhesive layer 759 on the upper surface 753 of the substrate 701 obtained in view (b). According to an example, the forming of an adhesive layer may be a deposition of the adhesive layer. According to another example, if substrate 750 is made of silicon, the forming of the adhesive layer may be a step of oxidation of the surface of the substrate to prepare a molecular bonding step.

View (c) further illustrates the forming of a capillary wick structure 761 in the bottom 763 of cavity 751. According to an example, capillary wick structure 761 is formed by using a step of Bosch etching of a pillar or of trenches using a lithography and an etching. According to an alternative embodiment, capillary wick structure 761 may be formed at an etch step common with the etching of channels 755.

Substrate 750 is thus ready for its assembly to the plate 700 described in view (c) of FIG. 7.

As previously mentioned, FIG. 9 illustrates the carrying out of steps of manufacturing of vapor chambers of the type of that described in relation with FIG. 2 by assembling the plate 700 of FIG. 7 and the substrate 750 of FIG. 8.

View (a) illustrates the positioning of the plate 700 of view (c) of FIG. 7 on the substrate 750 of view (c) of FIG. 8. More particularly, plate 700 is flipped, to have adhesive layer 707 in front of the adhesive layer 759 of substrate 750. Plate 700 is positioned above the substrate so that the portions of ductile material 709 are arranged in front of an end 757 of channel 755 emerging onto the cavity 751 of substrate 750, and that cavities 704 are arranged in front of another end of channel 755 intended to be coupled to a filling hole. Plate 700 and substrate 750 are aligned in front of each other with a maximum accuracy in the order of 1 μm.

View (a) further illustrates the bonding of plate 700 onto substrate 750. The bonding method used herein depends on the nature of adhesive layers 707 and 759. According to an example, the bonding may be a direct bonding, a hydrophilic direct bonding, a molecular bonding, a polymer bonding, a bonding using sintered glass, a eutectic sealing, a thermocompression bonding, etc. The bonding method may comprise polishing steps, anneals, pressurizations or the creation of vacuum. A method requiring no adhesive layers may also be used.

View (b) illustrates a step of filling of cavity 751 with a cooling fluid 760 of the type of the cooling fluid 319 described in relation with FIG. 2. The filling method used at this step is the following:
removing the gases present in cavity 751;
introducing cooling fluid 760 into cavity 751.

The gases present in cavity 751 are removed by creating vacuum, or quasi-vacuum, in cavity 751 by coupling it to a vacuum pump. The creation of vacuum may be followed by a degassing at high temperature of the walls of cavity 751, enabling to remove the residual chemical species that may be absorbed by the material of substrate 750.

The introduction of cooling fluid 760 is performed by injection of the precise volume of fluid 760 necessary to fill cavity 751. Fluid 760 may be degassed before its introduction. Fluid 760 is more particularly introduced into cavity 704 of plate 700 and then passes into channel 755 to fill cavity 751.

View (c) illustrates a step of closing of cavity 704. The filling of cavity 751 is ended, and the filling holes, that is, cavities 704, are tightly closed, for example, by a plug 761 installed by seal welding.

View (d) illustrates a step of sealing of channel 755 and of cavity 751. This sealing step comprises crushing ductile material 709 in channel 755 to fill a portion of channel 755 with ductile material 709, and thus close the access to cavity 751. This step may in practice be carried out in several ways, for example by thermocompression of ductile material 709, by pressing by means of a mold, etc. In FIG. 9, the method used is a pressing by means of a mold 765. The maximum pressing force that can be used is in the order of 100 kN. According to an example, mold 765 may be manufactured from a substrate made of the same material as substrate 750, for example, of silicon, or of a metal. Mold 765 may be the result of a succession of steps of masking, etching, and polishing, for example by nanoimprint. More particularly, the mold comprises raised areas arranged in front of the portions of plate 700 made of ductile material 709. Raised areas 767 may have a rectangular or trapezoidal cross-section.

According to a variant, to improve the tightness of the sealing of channel 755, the walls of channel 755 may be previously treated with an adhesion promoter material such as hexamethyldisilazane (HDMS), or by depositing on the wall a bonding layer, for example, made of a titanium and copper alloy.

A vapor chamber of the type of the vapor chamber 300 described in relation with FIG. 2 is thus obtained at the end of the method.

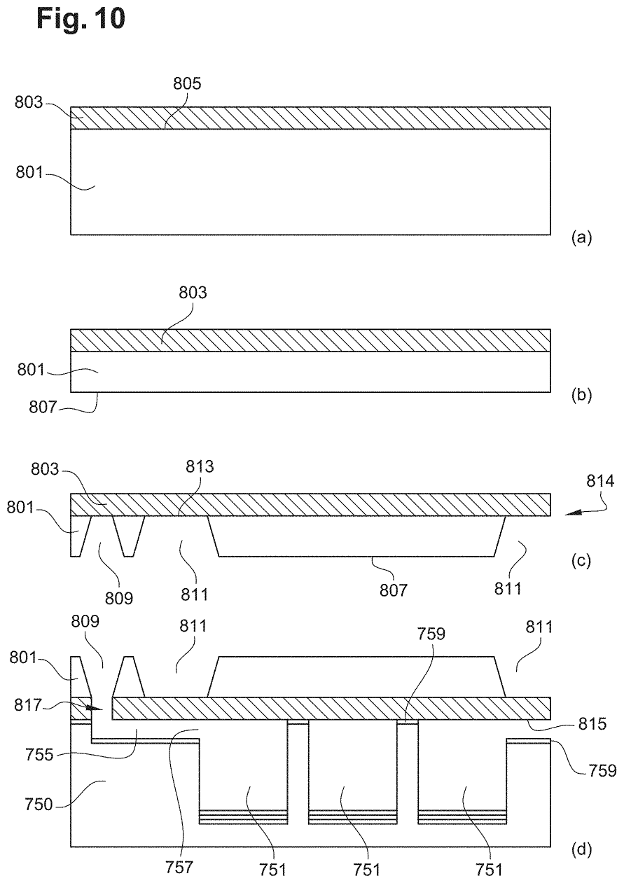

FIG. 10 shows four cross-section views (a), (b), (c), and (d) illustrating steps of a variant of the manufacturing method described in relation with FIGS. 7 to 9. More particularly, views (a) to (d) illustrate an alternative implementation mode of the method of manufacturing plate 700 described in relation with FIG. 7, and its assembly to the substrate 750 described in relation with FIG. 8.

View (a) illustrates a step of deposition, on a substrate 801, of a layer 803 of ductile material. Layer 803 is more particularly deposited on an upper surface of 805 of substrate 801 and fully covers this upper surface 805, it is then spoken of a full plate deposition. Substrate 801 is for example made of a semiconductor material, for example, a material comprising silicon. Layer 803 is made of a ductile material of the type of the ductile material 709 described in relation with FIG. 7, and its deposition method depends on the nature of the ductile material. Layer 803 has a thickness, for example, in the range from 20 to 200 μm.

View (b) illustrates a step of thinning of substrate 801 from its rear surface 807. The thinning method is for example a grinding method. The thickness of substrate 801 may then be smaller than 200 μm.

View (c) illustrates the etching of cavities 809 and 811 in substrate 801. In view (c), one cavity 809 is shown and two cavities 811 are shown. Cavities 809 and 811 are etched from the rear surface 807 of substrate 801 and all the way to a lower surface 813 of layer 803. Cavities 809 are intended to become filling holes, like the cavities 704 of FIG. 7. Like the cavities 704 of FIG. 7, cavities 809 may not be formed at this step, but after the assembly with substrate 750, or never be formed. Cavities 811 are intended to allow the crushing of the ductile material of layer 803 during the sealing of cavities 751. According to an example, when substrate 801 is made of silicon, the etch methods used may be via etching methods.

View (d) illustrates the assembly of the structure 814 of view (c) with the substrate 750 of view (c) of FIG. 8. As described in relation with FIG. 9, and more particularly view (a) of FIG. 9, the structure of view (c) is flipped, to have its upper surface 815 in front of the adhesive layer 759 of substrate 750. Like plate 700, structure 814 is positioned above the substrate so that cavities 811 are arranged in front of the end 757 of channel 755 emerging onto cavity 751, and so that cavities 809 are arranged in front of another end of channel 755 intended to be coupled to a filling hole. Structure 814 and substrate 750 are aligned in front of each other with a maximum accuracy in the order of 1 μm.

View (d) further illustrates the bonding of structure 814 to substrate 750. The bonding method used herein is similar to that disclosed in relation with view (a) of FIG. 9.

View (d) further illustrates the forming of the vapor chamber filling hole 817. Filling hole 817 is formed by etching of the portion of layer 803 present under cavity 809.

The rest of the vapor chamber manufacturing method is similar to that described in relation with views (b) to (d) of FIG. 9.

An advantage of the method of FIG. 10 is that it enables to decrease the number of manufacturing steps with respect to the method described in relation with FIGS. 7 to 9.

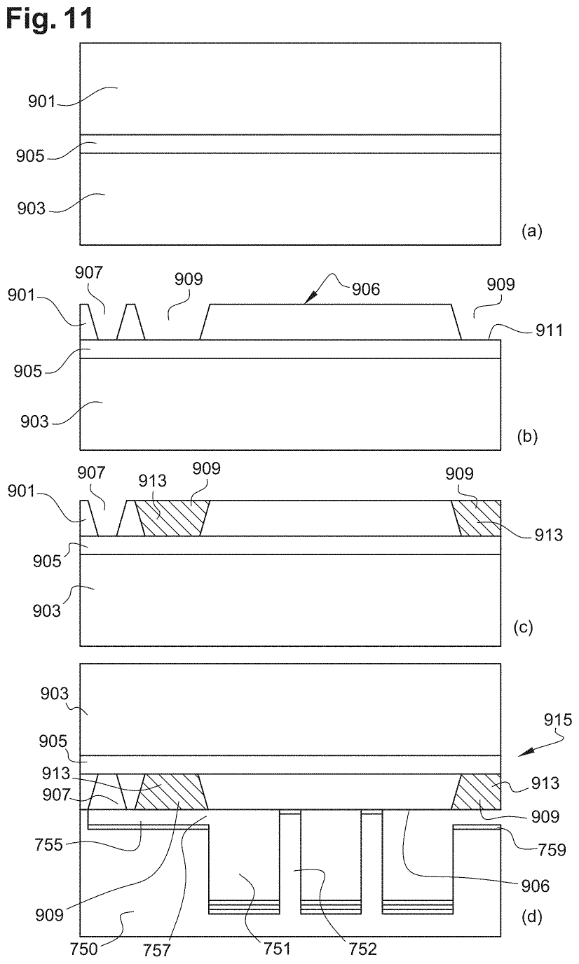

FIG. 11 shows four cross-section views (a), (b), (c), and (d) illustrating steps of another variant of the manufacturing method described in relation with FIGS. 7 to 9. More particularly, views (a) to (d) illustrate an alternative implementation mode of the method of manufacturing the plate 700 described in relation with FIG. 7.

View (a) illustrates the temporary bonding of a substrate 901 to a support substrate 903 via an adhesive layer 905. Substrates 901 and 903 are for example made of a semiconductor material, for example, a material comprising silicon. Adhesive layer 905 is for example a glue layer. It is a temporary bonding with the same type of glue as those used in 3D integration.

View (b) illustrates a step of thinning of substrate 901 from its upper surface 906. The thinning method is for example a grinding method. The thickness of substrate 901 may then be smaller than 200 μm.

View (b) further illustrates the etching of cavities 907 and 909 in substrate 901. In view (b), one cavity 907 is shown and two cavities 909 are shown. Cavities 907 and 909 are etched from an upper surface 906 of substrate 901 and all the way to an upper surface 911 of layer 905. Cavities 907 are intended to become filling holes, such as the cavities 704 of FIG. 7 or the cavities 809 of FIG. 10. Cavities 909 are intended to be filled with ductile material. The etch methods used are similar to those used for the etch step illustrated in relation with view (a) of FIG. 7.

View (c) illustrates a step of deposition of a ductile material 913 in cavities 909. Ductile material 913 is of the type of the ductile material 709 described in relation with FIG. 7, and its deposition method depends on its nature. Material 909 has a thickness, for example, in the range from 20 to 100 μm. For ductile material 913 to only be deposited in cavities 909, the rest of the structure is for example masked in a previous step.

View (d) illustrates the assembly of the structure of view (c) with the substrate 750 of view (c) of FIG. 8. As described in relation with FIG. 9, and more particularly view (a) of FIG. 9, the structure 915 of view (c) is flipped, to have its upper surface 906 in front of the adhesive layer 759 of substrate 750. Like plate 700, structure 915 is positioned above the substrate so that cavities 909 are arranged in front of the end 757 of channel 755 emerging onto cavity 751, and so that cavities 907 are arranged in front of another end of channel 755 intended to be coupled to a filling hole. Structure 915 and substrate 750 are aligned in front of each other with a maximum accuracy in the order of 1 μm.

View (d) further illustrates the bonding of structure 915 to substrate 750. The bonding method used herein is similar to that disclosed in relation with view (a) of FIG. 9.

The next step of the manufacturing method is not shown herein. This step comprises separating support substrate 903 from substrate 901. For this purpose, glue layer 905 and support substrate 903 are removed, for example, by a thermal treatment, by a UV treatment, or also a chemical treatment.

Like the method described in relation with FIG. 10, an advantage of the method of FIG. 11 is that it enables to form a plate having a thickness smaller than 200 μm.

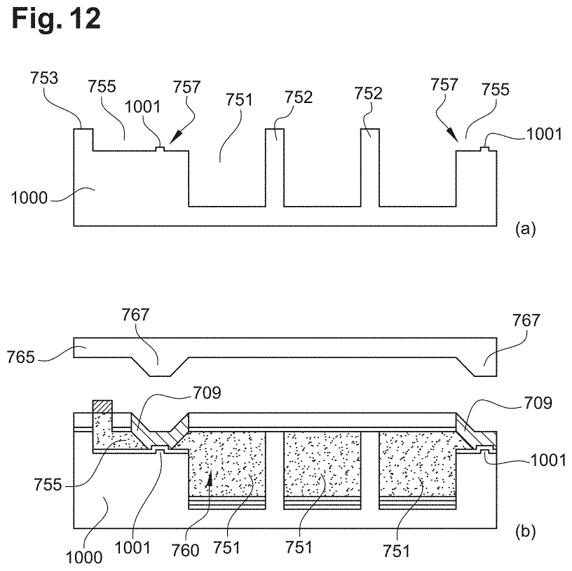

FIG. 12 shows two cross-section views (a) and (b) illustrating steps of another variant of the manufacturing method described in relation with FIGS. 7 to 9.

More particularly, views (a) and (b) illustrate an alternative embodiment where a substrate 1000, similar to the substrate 750 described in relation with FIG. 8, is associated with a plate 700. Substrate 1000 differs from substrate 750 in that it further comprises raised areas 1001 arranged in filling channels 755. Substrates 1000 and 750 having common elements, only their differences will be highlighted.

View (a) illustrates a step of preparation of a substrate 1000 similar to the step illustrated in relation with view (b) of FIG. 8. At this step, channel 755 is etched in substrate 1000, and raised areas 1001 are formed in this channel 755. Raised areas 1001 are arranged at the level of the ends 757 of channel 755 emerging onto cavity 751. Raised areas 1001 may have a height in the range from 1 to 50 μm, for example from 5 to 30 μm.

According to an example, the etching of raised areas 1001 and of channel 755 may be performed according to the following succession of steps:
first etching of the channel down to a first depth P1;
masking of the areas intended to form raised areas 1001; and
second etching forming channel 755 down to a second depth P2.

View (b) illustrates a step of manufacturing of a vapor chamber similar to the step illustrated in relation with view (d) of FIG. 9. At this step, channel 755 and cavity 751 are sealed by crushing of ductile material 709. Raised areas 1001 being arranged under the portions of plate 700 of ductile material 709, material 709 is crushed on raised areas 1001. This step may use the same methods as those described in relation with view (d) of FIG. 9, such as, for example, the use of mold 765. According to an example, not shown in FIG. 12, raised areas 767 may have their shape adapted to the shape of raised areas 1001.

An advantage of this embodiment is for the raised areas to enable to more efficiently seal the vapor chambers.

Another advantage of this embodiment is that the raised areas may enable to more easily position plate 700 above substrate 1000.

FIGS. 13 and 14 show cross-section views (a), (b), (c), (d), (e), (f), (g), and (h) illustrating steps of an implementation mode of a method of manufacturing an electronic system 1100.

View (a) of FIG. 13 illustrates the result of the assembly of an electronic chip 1101 to a substrate 1103. Chip 1101 may comprise one or a plurality of electronic components, and/or one or a plurality of integrated circuits. According to an example, electronic chip 1101 may be an electronic device adapted to the field of combinational logic, the radio frequency field, such as radars, telephony, “5G” technology, the field of power electronics, the field of electron optics, such as imaging, photonics, etc.

In the example illustrated in FIGS. 13 and 14, chip 1101 comprises at least two contacts 1105 arranged on the side of substrate 1103. Substrate 1103 is intended to be removed at the end of the method and has a support function. Substrate 1103 is for example made of a semiconductor material, for example, a material comprising silicon. According to an embodiment, substrate 1103 may be, in top view, a substrate of rectangular shape.

A sacrificial layer 1107 is formed between chip 1101 and substrate 1103. More particularly, layer 1107 rests directly on an upper surface 1109 of substrate 1103. Layer 1107 enables to ease the removal of substrate 1103 at the end of the method. According to an example, layer 1107 is a polymer sensitive to temperature, to a UV treatment or to a chemical treatment. A “Tape Revalapha” adhesive polymer of trade mark Nitto may be used.

A network of interconnection tracks 1111 is formed between chip 1101 and substrate 1103. More particularly, network 1111 is directly formed on layer 1107. In FIG. 13, network 1111 is represented as a single layer but, in practice, the network is formed of a more or less complex stack of electrically-insulating layers and of electrically-conductive tracks. The conductive tracks are for example metal tracks, such as copper tracks.

Connection terminals 1113 are formed on the network of interconnection tracks 1111. Connection terminals 1113 are for example under bump metallizations (UBM). According to an example, connection terminals 1113 are made of a metal or of a metal alloy, for example, an alloy comprising titanium, gold, titanium, chromium, or nickel.

Electronically-conductive links 1115 enable to couple connection terminals 1113 to the contacts 1105 of chip 1101. Links 1115 are for example solders, or vias.

A layer made of a ductile material 1117 is deposited over the entire upper surface of the structure. This layer 1117 allows a very good mechanical hold of the assembly. Ductile material 1117 is similar to the material 709 described in relation with FIG. 7, with the difference that material 1117 is, further, electrically insulating.

View (b) of FIG. 13 illustrates a step of thinning of an upper portion of the structure of view (a). More particularly, at this step, the layer of ductile material 1117, and more precisely an upper surface 1119 of the layer of ductile material 1117, is etched to reach an upper surface 1121 of electronic chip 1101. The etch method used at this step depends on the nature of ductile material 1117. According to an example, the etch method may be a grinding method.

View (c) of FIG. 13 illustrates a step of preparation of a substrate 1200 similar to the preparation of substrate 750 described in relation with FIG. 8. Thus, substrate 1200 comprises a cavity 1201 intended to receive a cooling fluid. Cavity 1201 is formed from an upper surface 1203 of substrate 1200. Substrate 1200 further comprises a filling channel 11205 emerging onto cavity 1201. According to the example shown in FIGS. 13 and 14, cavity 1201 comprises two pillars 1204 of the type of the pillars 651 described in relation with FIG. 6.

Substrate 1200 further comprises a lateral opening 1206 intended to form a horizontal filling hole of the type of the filling hole described in relation with view (b) of FIG. 5. Opening 1206 is coupled to an end of channel 1205.

View (d) of FIG. 13 illustrates another step of preparation of substrate 1200 where a capillary wick structure 1207 is formed in the bottom 1209 of cavities 1201. Structure 1207 is similar to the structure 307 described in relation with FIG. 2. In parallel, structure 1207 is also formed on surface 1121 of electronic chip 1101. This is illustrated in view (e).

View (e) of FIG. 13 illustrates a step of assembly of the structure of view (b) and of the substrate 1200 of view (d). Substrate 1200 is flipped, so that the opening of cavity 1201 is in front of the surface 1121 of electronic chip 1101. This assembly is similar to the bonding step described in relation with view (a) of FIG. 9. Thus, adhesive layers may have been previously formed on substrate 1200 and/or on the structure of view (b). According to an example, the assembly method may be a molecular bonding, a polymer bonding, a bonding using sintered glass, a thermocompression bonding, a metal-to-metal bonding, etc. According to an example, the use of a polymer material or a temporary bonding which does not resist temperatures higher than 200° C. can be envisaged. The assembly method may comprises polishing steps, anneals, pressurizations or the creation of vacuum.

Cavity 1201 is positioned to be in front of a potential hot spot of chip 1101.

View (f) of FIG. 13 illustrates the flipping of the structure obtained at Figure (e) and the removal of substrate 1103 and of sacrificial layer 1109. This removal may be performed, for example, by thermal treatment, by UV treatment, or by chemical treatment.

View (g) of FIG. 14 illustrates the filling of cavities 1201 with a cooling fluid 1150. Cooling fluid 1150 is similar to the cooling fluid 319 described in relation with FIG. 2. The filling method is similar to that described in relation with view (b) of FIG. 9, that is, a method comprising the removal of the gases present in cavity 1201 and then the filling of cavity 1201 with cooling fluid 1150. Fluid 1150 is introduced through filling hole 1206, and is then directed by channel 1205 into cavity 1201. Filling hole 1206 is then obstructed with a plug 1211.

View (h) of FIG. 14 illustrates the tight sealing of filling channel 1205 by crushing of ductile material 1117. This step is similar to the step of view (d) of FIG. 9. Cavity 1201 then forms a vapor chamber associated with chip 1101.

The association of a vapor chamber with a single electronic chip has been shown herein. It is however obvious to those skilled in the art that the method described in relation with FIGS. 13 and 14 may apply to the manufacturing of a vapor chamber common to a plurality of electronic chips. It is also obvious to those skilled in the art that the method described in relation with FIGS. 13 and 14 may apply to the manufacturing of a plurality of vapor chambers common to a single electronic chip.

Various embodiments and variants have been described. Those skilled in the art will understand that certain features of these various embodiments and variants may be combined, and other variants will occur to those skilled in the art.

In particular, the use of raised areas as described in relation with FIG. 12 is compatible with the plates of the embodiments described in relation with FIGS. 10 and 11. Similarly, raised areas may be envisaged in the method described in relation with FIGS. 13 and 14.

Finally, the practical implementation of the described embodiments and variations is within the abilities of those skilled in the art based on the functional indications given hereabove.

1. Method of manufacturing a vapor chamber, comprising the following successive steps:
(a) etching, in a first substrate, at least one first cavity extending from an upper surface of said first substrate, and at least one channel extending from the upper surface of said first substrate, a first end of said channel emerging into said at least one cavity;
(b) bonding a lower surface of a plate to the upper surface of said first substrate, the plate comprising at least one first region made of a ductile material arranged in front of said first end of said channel;
(c) filling said channel with a cooling fluid; and
(d) closing said cavity by applying a pressure on said region of ductile material of the plate to obstruct said first end of said channel.

2. Method according to claim 1, wherein, during step (d), said first cavity is tightly closed.

3. Method according to claim 1, wherein the first substrate is made of a material selected from the group comprising: a semiconductor material, silicon, a metal, a metal alloy, glass.

4. Method according to claim 1, wherein the ductile material is made of a polymer material or of a metal such as copper, silver, aluminum, gold, or an alloy of these metals.

5. Method according to claim 1, wherein, during step (a), second cavities are etched from the upper surface of said first substrate.

6. Method according to claim 5, wherein said channel couples said first cavity and said second cavities.

7. Method according to claim 6, wherein the first and second cavities are coupled in series by said channel.

8. Method according to claim 6, wherein the first and second cavities are coupled in parallel by said channel.

9. Method according to claim 1, wherein said plate comprises an opening arranged above a first portion of said channel.

10. Method according to claim 9, wherein the first portion of the channel is a second end of said channel.

11. Method according to claim 1, wherein said channel comprises a third end emerging onto an opening at the periphery of the first substrate.

12. Method according to claim 1, further comprising a step (e) executed between steps (b) and (c), during which a quasi-vacuum or vacuum is created in said at least one first cavity.

13. Method according to claim 1, wherein said first region of said plate extends along the entire length of said plate.

14. Method according to claim 1, wherein the cooling liquid is selected from the group comprising: water, helium, hydrogen, oxygen, nitrogen, sulfur, neon, argon, methane, krypton, mercury, ammonia (NH3), acetone (C3H6O), ethane (C2H6), pentane (C5H12), heptane (C7H16), ethanol (C2H5OH), methanol (CH3OH), ethylene glycol (C2H6O2), toluene (C7H8), naphthalene (C10H8), trichlorofluoromethane (CCl3F, also known under trade name Freon 11), dichlorofluoromethane (CHCl2F, also known under trade name Freon 21), chlorodifluoromethane (CHClF2, also known under trade name Freon 22), 1,1,2-Trichloro-1,2,2-trifluoroethane (C2Cl3F3, also known under trade name Freon 113), the fluid known under trade name Flutec PP2, the fluid known under trade name Flutec PP9, the fluid known under trade name Dowtherm, the fluid known under trade name Novec, and derivatives and mixtures of these fluids.

15. A vapor chamber manufactured according to the method according to claim 1.
